(19) United States
(12) Patent Application Publication
(10) Pub. No.: US 2016/0208431 A1
(43) Pub. Date: Jul. 21, 2016

(54) FLUORINE-CONTAINING SELF-LUBRICATING FABRIC COATING MATERIAL AND METHOD FOR PREPARING THE SAME

(71) Applicant: XIAMEN UNIVERSITY, Xiamen, Fujian (CN)

(72) Inventors: Lizong DAI, Xiamen (CN); Jie MAO, Xiamen (CN); Lingnan CHEN, Xiamen (CN); Yiting XU, Xiamen (CN); Birong ZENG, Xiamen (CN); Wuhui QIU, Xiamen (CN); Cunfeng SONG, Xiamen (CN); Wei'ang LUO, Xiamen (CN); Qilong KANG, Xiamen (CN)

(73) Assignee: XIAMEN UNIVERSITY, Xiamen (CN)

(21) Appl. No.: 14/910,938

(22) PCT Filed: Aug. 13, 2014
(86) PCT No.: PCT/CN2014/084274

§ 371 Date: Feb. 8, 2016

(30) Foreign Application Priority Data
Aug. 13, 2013 (CN) 201310352654.6

(51) Int. Cl. D06M 15/55; C23C 14/58; C09D 163/00

(52) U.S. Cl. CPC D06M 15/55; C09D 163/00; C23C 14/58; D06M 2200/40

(57) ABSTRACT

The present invention provides a fluorine-containing self-lubricating fabric coating material and method for preparing the same. The coating material consists of 30 to 70 pbw of fluorine resin, 10 to 40 pbw of a curing agent, 5 to 25 pbw of a reactive diluents, 0.5 to 5 pbw of a silane coupling agent and 0.5 to 3 pbw of a silicon surfactant. It is of high fluorine content and high stability. Besides, the coating material system with characteristics of self-lubricating and weather resistance is solvent-free, environmentally friendly, and has wide applications.

### FIELD OF THE INVENTION

The present invention relates to a fluorine-containing self-lubricating fabric coating material and method for preparing the same, and especially to a fabric coating material for self-lubricating joint bearing fabric backing strap and method for preparing the same.

### BACKGROUND OF THE INVENTION

Joint bearing is also known as spherical bearing consisting of an outer ring with internal sphere and an inner ring with external sphere. Self-lubricating joint bearing is a kind of special joint bearing without any lubricant. Self-lubricating joint bearing has the characteristics of simple structure, small size, high bearing capacity, low friction factor, high impact resistance, high corrosion resistance, small vibration, wide temperature range, long service life, maintenance-free and lubricant-free. It is widely used in construction machinery, heave truck, water conservancy facilities and military machinery.

In recent years, fabric liner typed self-lubricating joint bearing has attracted much research interest. Fabric liner as self-lubricating material is put between inner ring and outer ring of the joint bearing. It has the characteristics of simple structure, easily dismounted and assembled, high bearing capacity, long service life, flexible rotation and maintenance-free, therefore it has a wide application in equipments of aviation, aerospace, electric power, transportation, biomedicine and spinning, and becomes an indispensable unit of the equipments mentioned above.

The primary challenge of fabric liner typed self-lubricating joint bearing is wear-and-tear. Gap between inner ring and outer ring is enlarged owing to wear-and-tear, and fabric liner loses the lubricating function. As a result, the mechanism may be jammed and leads to catastrophic effect in some occasion such as landing gear. Therefore, fabric liner need a coating for protecting fabric and reduce friction factor.

Fluorine-containing polymer has properties of heat-resistance, corrosion resistance, surface hydrophobicity, electric insulating, low friction factor, biocompatibility and noninflammability, which is getting more and more attention. Fluorine presents maximum electronegativity with small atomic radius, and the C-F bond formed is of short bond length and large bond energy. Fluorine epoxy resin has properties of solvent resistance, oil resistance, friction and wear resistance and self-cleaning since fluorine is introduced into epoxy resin.

Chinese patent (No. CN 101348600A) discloses a self-lubricating epoxy resin and the method for preparing the same. It mixed lubricating oil capsule, epoxy resin and curing agent together for molding to get the self-lubricating epoxy resin material. This material is capable of reducing friction factor, however, lubricating oil capsule is unstable with bad durability, and the material can't be long-stem storage, which limits its application. Another Chinese patent (No.CN 102471917A) discloses a coating constructed by metal layer in which the lubricant capsule will release lubricant during wearing. The coating performs long lasting lubrication effect, however, the preparing processes are very complicated and the coating cannot be used on fabric or resin either. Another Chinese patent (No. CN 101717604 A) discloses an epoxy resin solid lubricating coating modified with graphite oxide and the method thereof, which overcomes the shortage of poor dispersivity of graphite solid lubricant in resin solution. However, the appearance of prepared coating is unsatisfactory which limits its application.

At present, there is still no report about fluorine-containing self-lubricating fabric coating material for fabric liner typed self-lubricating joint bearing..

### SUMMARY OF THE INVENTION

The objective of present invention is to provide a simple method for preparing self-lubricating coating wherein fluorine epoxy resin is synthesized by fluorine monomer together with epoxy chloropropane, and is cured by acid anhydrides curing agent with reactive diluents. It can overcome the disadvantage that epoxy resin coating is brittle and impermeable to fabric. It also improves the elasticity and plasticity, resulting in improving the performance of joint bearing. Moreover, fluorine epoxy resin coating of present invention is based on solvent-free curing process, which is environmentally friendly.

The fluorine-containing self-lubricating fabric coating material consists of: (a) 30 to 70 pbw (part by weight) of fluorine resin, (b) 10 to 40 pbw of a curing agent, (c) 5 to 25 pbw of a reactive diluents, (d) 0.5 to 5 pbw of a silane coupling agent and (e) 0.5 to 3 pbw of a silicon surfactant. The structure formula of the fluorine resin is

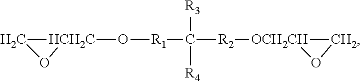

wherein both R₁ and R₂ refer to —(CF₂)ₙ— with n ranging from 1 to 18, or refer to the following aromatic groups with both R₃ and R₄ referring to —CF₃ or —CF₂CF₃.

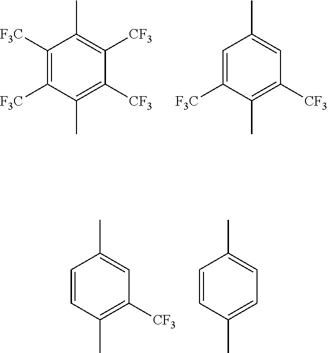

The method for preparing the fluorine resin comprises the steps of:
1. adding 30 to 40 pbw of fluorine monomer and 20 to 30 pbw of epoxy chloropropane into a reaction flask, stirring and heating up to 60˜70° C.;
2. mixing 5 to 10 pbw of NaOH and 15 to 20 pbw of water to prepare lye solution, and dropping the lye solution into the reaction flask within 1 to 1.5 hours at the temperature of 60 to 70° C.;
3. refluxing the reactant at 70° C. to 1.5 hours until the system presents a whitish yellow color;
4. adding deionized water together with toluene, stirring until homogenous, standing and layering the system repeatedly to remove water, distilling separated organic layer under reduced pressure to remove toluene and unreacted epoxy chloropropane so that a light yellow viscous resin is provided.

In a preferred embodiment, the curing agent is acid anhydrides used in conjunction with fluorine epoxy resin including acid anhydrides, o-phthalic anhydride, pyromellitic dianhydride, methylcyclohexene tetracarboxylic dianhydride and cis-butenedioic anhydride.

In a preferred embodiment, the reactive diluents is at least one component selected from the group consisting of 1,6-hexanediol diacrylate, 2-hydroxyethyl methacrylate, cresyl glycidyl ether, castor oil glycidyl ether, and ethylene glycol diglycidyl ether. In a preferred embodiment, the general formula of the silane coupling agent is Y(CH₂)ₙSiX₃, wherein n=0˜3, X refers to at least one kind of group selected from the group consisting of chlorine, methoxyl, oxethyl, methoxyethoxy and acetoxyl, and Y refers to amine or/and epoxy.

In a preferred embodiment, the silicon surfactant is at least one kind of silicon surfactant selected from the group consisting of silane-based, oxosilane-based, anionic, cationic and nonionic.

A method for preparing the fluorine-containing self-lubricating fabric coating material mentioned above comprises the steps of: dissolving a silane coupling agent and a curing agent into a reactive diluents successively according to proportioning of the coating, stirring for 0.5 to 1 hour to obtain homogenous solution; adding fluorine epoxy resin into the solution under stirring and stirring the mixture for 1 to 2 hours to get the coating material; painting the coating material on clean fabric, drying at 40 to 60° C. by air-circulating oven for 1 to 2 hours and curing at 150 to 170° C. under 0.2 to 0.3 Mpa for 2 to 3 hours when used.

The advantages of present invention are:
(1) Fluorine epoxy resin with excellent bonding property of epoxy resin and modification of fluorine reduces friction factor of coating and improves self-lubricating as well, which improves retention of fabric and prevents wearing caused by fabric displacement. The coating is especially applicable to polytetrafluoroethylene fabric frequently used on self-lubricating joint bearing.
(2) The coating material is capable of impregnating fabric via employing reactive diluents. Further, since acid anhydrides is used as curing agent, the elasticity and plasticity of produced coating material is improved, and the load capacity of bearing is also improved as stress is dispersed.
(3) Reactive diluents entering into the reaction is used to replace traditional volatile solvent, which is environmentally friendly.

### BRIEF DESCRIPTION OF THE DRAWINGS

FIG. 1 illustrates ¹³C NMR of fluorine resin of embodiment 1;

FIG. 2 illustrates FTIR of fluorine resin of embodiment 1.

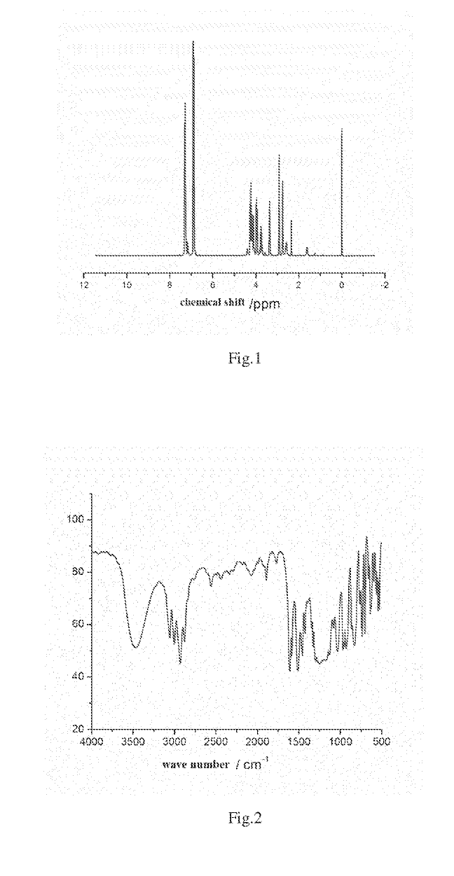

### DETAILED DESCRIPTION OF THE EMBODIMENTS

The present invention will be further described with the drawings and the embodiments.

### Embodiment 1

35 g cis-butenedioic anhydride, 15 g reactive diluents of 669, 0.5 g aminopropyl triethoxy silane coupling agent and 0.5 g silicon surfactant of SH-200 are mixed and ultrasonic dispersed for 1 hour, then 60 g fluorine resin is added with 10 times amount and the mixture is stirred for 1 hour in low speed dispersion machine to obtain self-lubricating coating.

Fabric is washed by acetone and coated by the self-lubricating coating, then dried at 50° C. by air-circulating oven for 1 hour and cured at 160° C. (heating up in 2 hours) under 0.2 Mpa for 2 hours. The friction factor of cured fabric is 0.032 with a wear rate of 2.8±0.7 (×10⁻⁶ mm³/Nm).

The preparation of fluorine resin is as follows:
1. 30 g 1,1-bis-(4-hydroxyphenyl)-1-pheny-2,2,2-trifluoroethane and 28 g epichlorohydrin are added into a reaction flask with stirrer and temperature control unit, then the mixture is stirred and heated up to 65° C.
2. 6 g NaOH and 17 ml deionized water are mixed to prepare lye solution, the lye solution is dropped into the reaction flask within 1 5 hours at the temperature of 65° C.
3. The reactant is refluxed at 70° C. to 1.5 hours until the system presents a whitish yellow color.
4. 27 mL deionized water and 54 mL toluene are added and stirred until homogenous, the system is layered after standing and water is removed, organic layer is separated after standing and layering repeatedly for some times, then the organic layer is distilled under reduced pressure to remove toluene and unreacted epoxy chloropropane so that a light yellow viscous resin is obtained.

### Embodiment 2

30 g cis-butenedioic anhydride, 20 g reactive diluents of 669, 1 g aminopropyl triethoxy silane coupling agent and 0.5 mL silicon surfactant of SH-200 are mixed and ultrasonic dispersed for 1 hour, then 60 g fluorine resin is added with 10 times amount and the mixture is stirred for 1 hour in low speed dispersion machine to obtain self-lubricating coating.

Fabric is washed by acetone and coated by the self-lubricating coating, then dried at 50° C. by air-circulating oven for 1 hour and cured at 160° C. (heating up in 2 hours) under 0.2 Mpa for 2 hours. The friction factor of cured fabric is 0.036 with a wear rate of 2.7±0.7 (×10⁻⁶ mm³/Nm).

The preparation of fluorine resin is as follows:
1. 35 g 1,1-bis-(4-hydroxyphenyl)-1-(3-trifluoromethyl penyl)-2,2,2-trifluoroethane and 26 g epichlorohydrin are added into a reaction flask with stirrer and temperature control unit, then the mixture is stirred and heated up to 65° C.
2. 7 g NaOH and 15 mL deionized water are mixed to prepare lye solution, the lye solution is dropped into the reaction flask within 1 5 hours at the temperature of 65° C.
3. The reactant is refluxed at 70° C. to 1.5 hours until the system presents a whitish yellow color.
4. 27 mL deionized water and 54 mL toluene are added and stirred until homogenous, the system is layered after standing and water is removed, organic layer is separated after standing and layering repeatedly for some times, then the organic layer is distilled under reduced pressure to remove toluene and unreacted epoxy chloropropane so that a light yellow viscous resin is obtained.

### Embodiment 3

35 g cis-butenedioic anhydride, 20 g reactive diluents of 669, 1 g aminopropyl triethoxy silane coupling agent and 1 g silicon surfactant of SH-200 are mixed and ultrasonic dispersed for 1 hour, then 65 g fluorine resin is added with 10 times amount and the mixture is stirred for 1 hour in low speed dispersion machine to obtain self-lubricating coating.

Fabric is washed by acetone and coated by the self-lubricating coating, then dried at 50° C. by air-circulating oven for 1 hour and cured at 160° C. (heating up in 2 hours) under 0.2 Mpa for 2 hours. The friction factor of cured fabric is 0.035 with a wear rate of 2.9±0.7 (×10⁻⁶ mm³/Nm).

The preparation of fluorine resin is as follows:
1. 30 g 2,2-bis-(hydroxyphenyl)-1,1,3,3,3-hexafluoropropane and 26 g epichlorohydrin are added into a reaction flask with stirrer and temperature control unit, then the mixture is stirred and heated up to 65° C.
2. 6 g NaOH and 15 mL deionized water are mixed to prepare lye solution; the lye solution is dropped into the reaction flask within 1 5 hours at the temperature of 65° C.
3. The reactant is refluxed at 70° C. to 1.5 hours until the system presents a whitish yellow color.
4. 27 ml deionized water and 54 ml toluene are added and stirred until homogenous, the system is layered after standing and water is removed, organic layer is separated after standing and layering repeatedly for some times, then the organic layer is distilled under reduced pressure to remove toluene and unreacted epoxy chloropropane so that a light yellow viscous resin is obtained.

### Embodiment 4

30 g cis-butenedioic anhydride, 15 g reactive diluents of 669, 1 g aminopropyl triethoxy silane coupling agent and 0.5 g silicon surfactant of SH-200 are mixed and ultrasonic dispersed for 1 hour, then 50 g fluorine resin is added with 10 times amount and the mixture is stirred for 1 hour in low speed dispersion machine to obtain self-lubricating coating.

Fabric is washed by acetone and coated by the self-lubricating coating, then dried at 50° C. by air-circulating oven for 1 hour and cured at 160° C. (heating up in 2 hours) under 0.2 Mpa for 2 hours. The friction factor of cured fabric is 0.034 with a wear rate of 2.9±0.7 (×10⁻⁶ mm³/Nm).

The preparation of bisphenol AF epoxy resins refers to embodiment 3.

Although the present invention has been described with reference to the preferred embodiments thereof for carrying out the patent for invention, it is apparent to those skilled in the art that a variety of modifications and changes may be made without departing from the scope of the patent for invention which is intended to be defined by the appended claims.

### INDUSTRIAL APPLICABILITY

The present invention provides fluorine epoxy resin synthesized by fluorine monomer together with epoxy chloropropane and cured by acid anhydrides curing agent with reactive diluents, which overcomes the disadvantage that epoxy resin coating is brittle and impermeable to fabric. It also improves the elasticity and plasticity, resulting in improving the performance of joint bearing.

1. A fluorine-containing self-lubricating fabric coating material consists of:
(a) 30 to 70 pbw of fluorine resin, (b) 10 to 40 pbw of a curing agent, (c) 5 to 25 pbw of a reactive diluents, (d) 0.5 to 5 pbw of a silane coupling agent and (e) 0.5 to 3 pbw of a silicon surfactant; wherein
the structure formula of the fluorine resin is 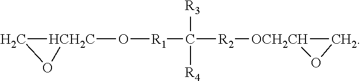
with both R₁ and R₂ refer to —(CF₂)ₙ— and n ranging from 1 to 18, or refer to the following aromatic groups with both R₃ and R₄ referring to —CF₃ or —CF₂CF₃.

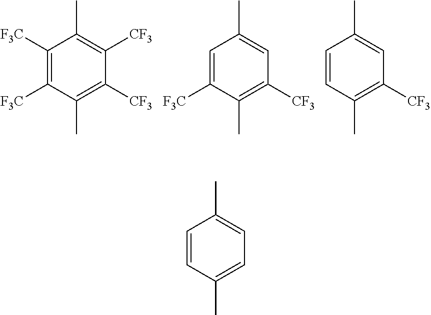

2. The fluorine-containing self-lubricating fabric coating material according to claim 1, comprises the following preparation steps:
adding 30 to 40 pbw of fluorine monomer and 20 to 30 pbw of epoxy chloropropane into a reaction flask, stirring and heating up to 60˜70 □;
mixing 5 to 10 pbw of NaOH and 15 to 20 pbw of water to prepare lye solution and dropping the lye solution into the reaction flask within 1 to 1.5 hours at the temperature of 60 to 70 □;
refluxing the reactant at 70 □ to 1.5 hours until the system presents a whitish yellow color;
adding deionized water together with toluene, stirring until homogenous, standing and layering the system repeatedly to remove water, distilling separated organic layer under reduced pressure to remove toluene and unreacted epoxy chloropropane so that a light yellow viscous resin is obtained.

3. The fluorine-containing self-lubricating fabric coating material according to claim 1, has the curing agent which is acid anhydrides used in conjunction with fluorine epoxy resin including acid anhydrides, o-phthalic anhydride, pyromellitic dianhydride, methylcyclohexene tetracarboxylic dianhydride, and cis-butenedioic anhydride.

4. The fluorine-containing self-lubricating fabric coating material according to claim 3, has the reactive diluents which is at least one component selected from the group consisting of 1,6-hexanediol diacrylate, 2-hydroxyethyl methacrylate, cresyl glycidyl ether, castor oil glycidyl ether, and ethylene glycol diglycidyl ether.

5. The fluorine-containing self-lubricating fabric coating material according to claim 4, includes the silane coupling agent with the general formula being Y(CH₂)ₙSiX₃, wherein n=0˜3, and X refers to at least one group selected from the group consisting of chlorine, methoxyl, oxethyl, methoxyethoxy and acetoxyl, and Y refers to amine or/and epoxy group.

6. The fluorine-containing self-lubricating fabric coating material according to claim 5, includes the silicon surfactant which is at least one kind of silicon surfactant selected from the group consisting of silane-based, oxosilane-based, anionic, cationic and nonionic.

7. A method for preparing the fluorine-containing self-lubricating fabric coating material according to claim 1 comprises the steps of:
dissolving a silane coupling agent and a curing agent into a reactive diluents successively according to proportioning of the coating, stirring for 0.5 to 1 hour to obtain homogenous solution;
adding fluorine epoxy resin into the solution under stirring and stirring the mixture for 1 to 2 hours to get the coating material; painting the coating material on clean fabric, drying at 40 to 60° C. by air-circulating oven for 1 to 2 hours and curing at 150 to 170° C. under 0.2 to 0.3 Mpa for 2 to 3 hours when used.

8. The fluorine-containing self-lubricating fabric coating material according to claim 2, has the curing agent which is acid anhydrides used in conjunction with fluorine epoxy resin including acid anhydrides, o-phthalic anhydride, pyromellitic dianhydride, methylcyclohexene tetracarboxylic dianhydride, and cis-butenedioic anhydride.

9. The fluorine-containing self-lubricating fabric coating material according to claim 8, has the reactive diluents which is at least one component selected from the group consisting of 1,6-hexanediol diacrylate, 2-hydroxyethyl methacrylate, cresyl glycidyl ether, castor oil glycidyl ether, and ethylene glycol diglycidyl ether.

10. The fluorine-containing self-lubricating fabric coating material according to claim 9, includes the silane coupling agent with the general formula being Y(CH₂)ₙSiX₃, wherein n=0˜3, and X refers to at least one group selected from the group consisting of chlorine, methoxyl, oxethyl, methoxyethoxy and acetoxyl, and Y refers to amine or/and epoxy group.

11. The fluorine-containing self-lubricating fabric coating material according to claim 10, includes the silicon surfactant which is at least one kind of silicon surfactant selected from the group consisting of silane-based, oxosilane-based, anionic, cationic and nonionic.

12. A method for preparing the fluorine-containing self-lubricating fabric coating material according to claim 2 comprises the steps of:
dissolving a silane coupling agent and a curing agent into a reactive diluents successively according to proportioning of the coating, stirring for 0.5 to 1 hour to obtain homogenous solution;
adding fluorine epoxy resin into the solution under stirring and stirring the mixture for 1 to 2 hours to get the coating material; painting the coating material on clean fabric, drying at 40 to 60° C. by air-circulating oven for 1 to 2 hours and curing at 150 to 170° C. under 0.2 to 0.3 Mpa for 2 to 3 hours when used.

13. A method for preparing the fluorine-containing self-lubricating fabric coating material according to claim 3 comprises the steps of:
dissolving a silane coupling agent and a curing agent into a reactive diluents successively according to proportioning of the coating, stirring for 0.5 to 1 hour to obtain homogenous solution;
adding fluorine epoxy resin into the solution under stirring and stirring the mixture for 1 to 2 hours to get the coating material; painting the coating material on clean fabric, drying at 40 to 60° C. by air-circulating oven for 1 to 2 hours and curing at 150 to 170° C. under 0.2 to 0.3 Mpa for 2 to 3 hours when used.

14. A method for preparing the fluorine-containing self-lubricating fabric coating material according to claim 8 comprises the steps of:
dissolving a silane coupling agent and a curing agent into a reactive diluents successively according to proportioning of the coating, stirring for 0.5 to 1 hour to obtain homogenous solution;
adding fluorine epoxy resin into the solution under stirring and stirring the mixture for 1 to 2 hours to get the coating material; painting the coating material on clean fabric, drying at 40 to 60° C. by air-circulating oven for 1 to 2 hours and curing at 150 to 170° C. under 0.2 to 0.3 Mpa for 2 to 3 hours when used.

15. A method for preparing the fluorine-containing self-lubricating fabric coating material according to claim 4 comprises the steps of:
dissolving a silane coupling agent and a curing agent into a reactive diluents successively according to proportioning of the coating, stirring for 0.5 to 1 hour to obtain homogenous solution;
adding fluorine epoxy resin into the solution under stirring and stirring the mixture for 1 to 2 hours to get the coating material; painting the coating material on clean fabric, drying at 40 to 60° C. by air-circulating oven for 1 to 2 hours and curing at 150 to 170° C. under 0.2 to 0.3 Mpa for 2 to 3 hours when used.

16. A method for preparing the fluorine-containing self-lubricating fabric coating material according to claim 9 comprises the steps of:
dissolving a silane coupling agent and a curing agent into a reactive diluents successively according to proportioning of the coating, stirring for 0.5 to 1 hour to obtain homogenous solution;
adding fluorine epoxy resin into the solution under stirring and stirring the mixture for 1 to 2 hours to get the coating material; painting the coating material on clean fabric, drying at 40 to 60° C. by air-circulating oven for 1 to 2 hours and curing at 150 to 170° C. under 0.2 to 0.3 Mpa for 2 to 3 hours when used.

17. A method for preparing the fluorine-containing self-lubricating fabric coating material according to claim 5 comprises the steps of:
dissolving a silane coupling agent and a curing agent into a reactive diluents successively according to proportioning of the coating, stirring for 0.5 to 1 hour to obtain homogenous solution;
adding fluorine epoxy resin into the solution under stirring and stirring the mixture for 1 to 2 hours to get the coating material; painting the coating material on clean fabric, drying at 40 to 60° C. by air-circulating oven for 1 to 2 hours and curing at 150 to 170° C. under 0.2 to 0.3 Mpa for 2 to 3 hours when used.

18. A method for preparing the fluorine-containing self-lubricating fabric coating material according to claim 10 comprises the steps of:
dissolving a silane coupling agent and a curing agent into a reactive diluents successively according to proportioning of the coating, stirring for 0.5 to 1 hour to obtain homogenous solution;
adding fluorine epoxy resin into the solution under stirring and stirring the mixture for 1 to 2 hours to get the coating material; painting the coating material on clean fabric, drying at 40 to 60° C. by air-circulating oven for 1 to 2 hours and curing at 150 to 170° C. under 0.2 to 0.3 Mpa for 2 to 3 hours when used.

19. A method for preparing the fluorine-containing self-lubricating fabric coating material according to claim 6 comprises the steps of:
dissolving a silane coupling agent and a curing agent into a reactive diluents successively according to proportioning of the coating, stirring for 0.5 to 1 hour to obtain homogenous solution;
adding fluorine epoxy resin into the solution under stirring and stirring the mixture for 1 to 2 hours to get the coating material; painting the coating material on clean fabric, drying at 40 to 60° C. by air-circulating oven for 1 to 2 hours and curing at 150 to 170° C. under 0.2 to 0.3 Mpa for 2 to 3 hours when used.

20. A method for preparing the fluorine-containing self-lubricating fabric coating material according to claim 11 comprises the steps of:
dissolving a silane coupling agent and a curing agent into a reactive diluents successively according to proportioning of the coating, stirring for 0.5 to 1 hour to obtain homogenous solution;
adding fluorine epoxy resin into the solution under stirring and stirring the mixture for 1 to 2 hours to get the coating material; painting the coating material on clean fabric, drying at 40 to 60° C. by air-circulating oven for 1 to 2 hours and curing at 150 to 170° C. under 0.2 to 0.3 Mpa for 2 to 3 hours when used.
